(19) United States
(12) Patent Application Publication
(10) Pub. No.: US 2009/0209097 A1
(43) Pub. Date: Aug. 20, 2009

(54) METHOD OF FORMING INTERCONNECTS

(76) Inventors: Thomas Schulz, Heverlee (BE); Sergei Postnikov, Brussels (BE); Hans-Joachim Barth, Munich (DE); Klaus von Arnim, Herzhorn (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/032,295

(22) Filed: Feb. 15, 2008

(51) Int. Cl. H01L 21/4763

(52) U.S. Cl. 438/638; 257/E21.495

(57) ABSTRACT

A method of forming interconnects includes etching a first set of openings in a hard mask using a first photo resist layer with a first pattern of openings as a first etch mask, and etching a second set of openings in the hard mask using a second photo resist layer with a second pattern of openings as a second etch mask. The method includes shrinking the openings in at least one of the first pattern and the second pattern prior to etching the openings in the hard mask.

### BACKGROUND

Design shrink and scaling of devices are driving factors in the semiconductor industry. As the feature size of integrated circuits continues to decrease, it becomes more difficult to fabricate certain structures. For example, small contacts and other structures can be very difficult to create due to difficulties that may arise in creating an appropriate photo mask that can be used to print the contacts. When creating small contacts, for example, small pinholes are created in the photo mask, which can lead to imaging difficulties. Furthermore, if the small contacts are placed close together, their close proximity may cause imaging problems.

The scaling of minimum feature size has previously been addressed by reducing the wavelength of the light source used in lithography tools (e.g., light source wave lengths include: 436 nm (g-line), 365 nm (i-line), 248 nm (KrF), 193 nm (ArF)). For wavelengths less than 193 nm, appropriate light sources are very expensive or are not readily available, and other next generation lithography techniques are being developed (e.g., Immersion Lithography, Extreme Ultraviolet (EUV), Electron Projection, Nanoimprint, etc.). However, these developments are not well tested, and may be complex and expensive.

### SUMMARY

One embodiment provides a method of forming interconnects. The method includes etching a first set of openings in a hard mask using a first photo resist layer with a first pattern of openings as a first etch mask, and etching a second set of openings in the hard mask using a second photo resist layer with a second pattern of openings as a second etch mask. The method includes shrinking the openings in at least one of the first pattern and the second pattern prior to etching the openings in the hard mask.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A is a diagram illustrating an example library element.

FIG. 1B is a diagram illustrating the library element shown in FIG. 1A after a library area shrink of about twenty percent with cancelling redundant vias.

FIG. 2A is a diagram illustrating the library element shown in FIG. 1A after a library area shrink of about twenty percent without cancelling redundant contacts according to one embodiment.

FIG. 2B is a diagram illustrating the library element shown in FIG. 1A after a library area shrink of about twenty percent without cancelling redundant contacts according to another embodiment.

FIG. 3 is a diagram illustrating a method for forming interconnects using a combination of a double exposure/patterning lithography process and a plasma-assisted shrink process according to one embodiment.

FIG. 4 is a diagram illustrating a method for forming interconnects of different sizes using a combination of a double exposure/patterning lithography process and a plasma-assisted shrink process according to one embodiment.

FIGS. 5A-5F are diagrams illustrating a top view of a structure and illustrating a method for forming interconnects of different sizes using a combination of a double exposure/patterning lithography process and a plasma-assisted shrink process according to one embodiment.

FIGS. 6A-6F are diagrams illustrating cross-sectional views of the structures shown in FIGS. 5A-5F, respectively, according to one embodiment.

FIG. 7 is a diagram illustrating a plasma-assisted shrink process according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment provides a method for shrinking the occupied area of library elements while keeping the original layout intact, thereby allowing the placement of additional contacts or redundant vias for yield enhancement in areas where it could normally not be accomplished due to design rule constraints, such as lithography constraints. The method according to one embodiment allows a relaxation of some design rule restrictions, or the use of more aggressive scaled designs for area gain, yield improvement and/or cost reduction.

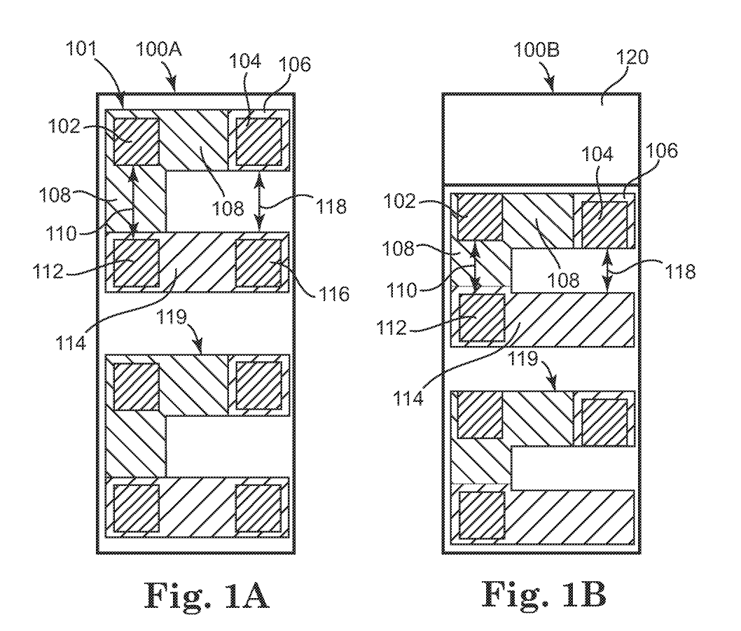

FIG. 1A is a diagram illustrating an example library element 100A. Library element 100A includes elements 101 and 119. Element 101 includes contacts 102, 104, 112, and 116, active area 108, and poly conductor regions 106 and 114. Element 119 includes the same features and is configured in the same manner as element 101. Two example design rules are also illustrated in FIG. 1A. Arrow 110 represents a standard distance between contacts, and arrow 118 represents a standard distance between poly conductor regions.

FIG. 1B is a diagram illustrating the library element 100A shown in FIG. 1A after a library area shrink of about twenty percent. The library element 100A after the shrink is represented by reference number 100B. The shrink results in a twenty percent area gain, which is represented by block 120. It will be understood that a design shrink is not limited to a one-dimensional shrink, such as that shown in FIG. 1B, but rather it can be done in more than one dimension. To accomplish the shrink shown in FIG. 1B, some design rules are violated, and the distances 110 and 118 are reduced to the limit of the capability of the lithography. The layout itself is also modified to reach the twenty percent area gain. For example, contact 102 is shifted upward, which brings the contact 102 to the top border of the active area 108. If it is assumed that certain contacts cannot easily be shifted, such as poly conductor contacts (e.g., contact 112 and 116), then redundant contacts may be cancelled. In the illustrated example, the second poly conductor contact 116 (FIG. 1A) in the bottom right corner has been cancelled from the library element 100B shown in FIG. 1B. A problem with cancelling redundant contacts in a critical path, however, is that reliability and yield are reduced.

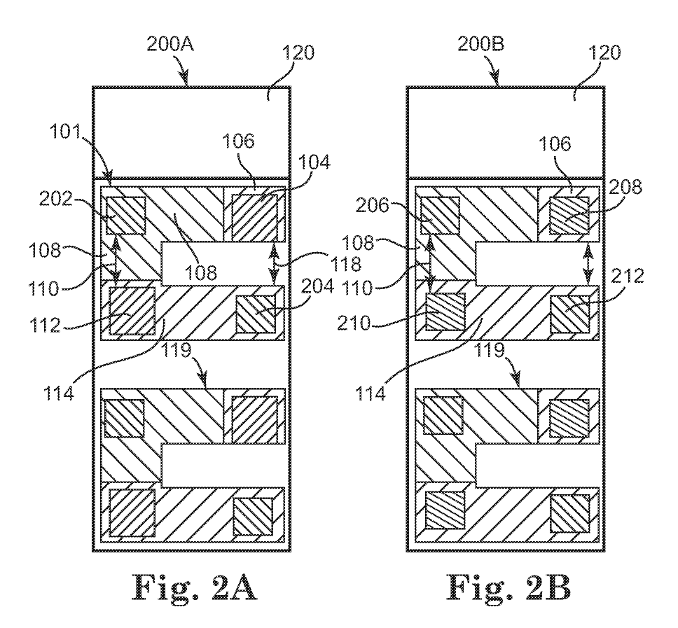

FIG. 2A is a diagram illustrating the library element 100A shown in FIG. 1A after a library area shrink of about twenty percent without cancelling redundant contacts according to one embodiment. The library element 100A after the shrink is represented by reference number 200A. The contacts 102 and 116 of library element 100A have been replaced in library element 200A by smaller contacts 202 and 204, respectively. The use of different contact sizes allows the redundant contact 116 (FIG. 1A) to be retained (as smaller contact 204), and results in smaller design rule violations or no design rule violations in accomplishing the layout shrink. A method for forming conductive interconnects (e.g., contacts, or conductive vias that interconnect two metal layers) of different sizes according to one embodiment is described in further detail below.

FIG. 2B is a diagram illustrating the library element 100A shown in FIG. 1A after a library area shrink of about twenty percent without cancelling redundant contacts according to another embodiment. The library element 100A after the shrink is represented by reference number 200B. The contacts 102, 104, 112, and 116 of library element 100A have been replaced in library element 200B by smaller contacts 206, 208, 210, and 212, respectively. The use of smaller contact sizes allows the redundant contact 116 (FIG. 1A) to be retained (as smaller contact 212), and results in smaller design rule violations or no design rule violations in accomplishing the layout shrink. A method for forming reduced size contacts or other interconnects according to one embodiment is described in further detail below.

As mentioned above in the Background section, the next generation lithography techniques being developed will be complex and expensive. Therefore, the use of current established methods and tools is beneficial. Double exposure and double patterning techniques are promising candidates for 32 nm technologies and beyond. However, even with these approaches, the contacts or other interconnects (e.g., conductive vias) cannot typically be placed in areas where prohibited by the design rules. One embodiment uses a combination of a double exposure lithography process and a shrink process to provide contacts of varying sizes in a single layout. The contacts of varying sizes are provided in a single layer of a semiconductor device in one embodiment.

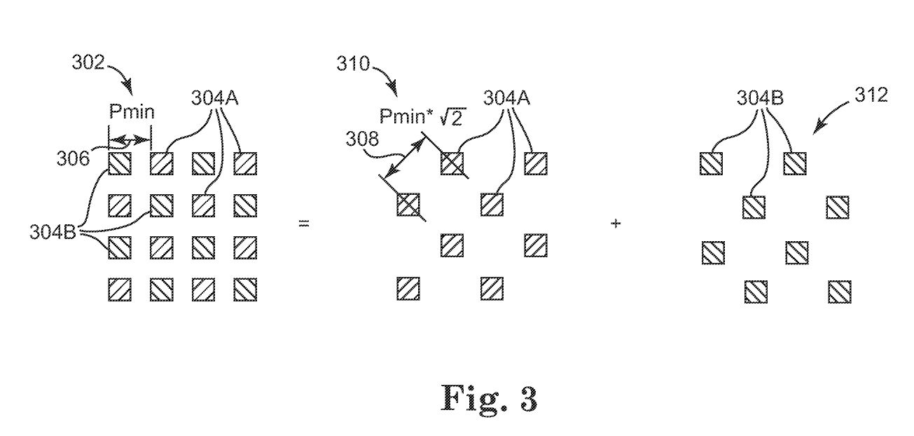

FIG. 3 is a diagram illustrating a method for forming interconnects using a combination of a double exposure lithography process and a plasma-assisted shrink process according to one embodiment. Layout 302 represents a desired layout of interconnects. The layout 302 includes a first set of interconnects 304A and a second set of interconnects 304B in a checkerboard pattern. The minimum pitch, Pmin, of the interconnects in layout 302 is represented by arrow 306. It is assumed that the minimum pitch, Pmin, is beyond the resolution capabilities of the lithography using a single exposure. Thus, in the illustrated embodiment, a first photo mask is used to form the first set of interconnects 304A during a first exposure step (represented by reference number 310), and the first set of interconnects 304A is then optionally scaled using a shrink process. A second photo mask is then used to form the second set of interconnects 304B during a second exposure step (represented by reference number 312), and the second set of interconnects 304B is then optionally scaled using a shrink process.

The double exposure allows patterning of the interconnects 304A and 304B in layout 302 at a sub-resolution pitch (i.e., beyond the resolution capabilities of the lithography using a single exposure). As shown at 310 in FIG. 3, the minimum pitch of the first set of interconnects 304A is represented by arrow 308, and is equal to Pmin times the square root of two. The minimum pitch of the second set of interconnects 304B is also equal to Pmin times the square root of two. Thus, the two sets of interconnects 304A and 304B are separately formed with a larger minimum pitch to produce a layout 302 that includes interconnects at a sub-resolution pitch.

A shrink process may be used in one embodiment after either or both of the exposure steps. By using no shrink or a less aggressive shrink (i.e., a lesser number of shrink cycles) after one of the exposure steps, and using a more aggressive shrink (i.e., a greater number of shrink cycles) after the other exposure step, interconnects with two different sizes may be formed.

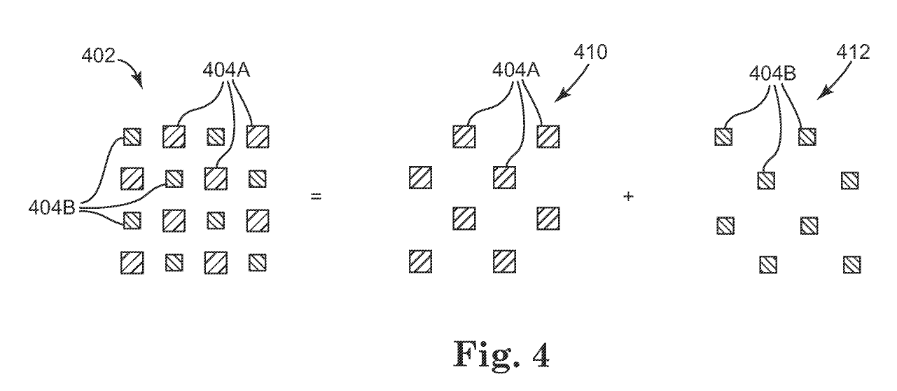

FIG. 4 is a diagram illustrating a method for forming interconnects of different sizes using a combination of a double exposure lithography process and a plasma-assisted shrink process according to one embodiment. Layout 402 represents a desired layout of interconnects. The layout 402 includes a first set of interconnects 404A having a first (larger) size and a second set of interconnects 404B having a second (smaller) size. The two sets of interconnects 404A and 404B are in a checkerboard pattern. In the illustrated embodiment, a first photo mask is used to form the first set of interconnects 404A during a first exposure step (represented by reference number 410), and the first set of interconnects 404A is then optionally scaled using a shrink process. A second photo mask is then used to form the second set of interconnects 404B during a second exposure step (represented by reference number 412), and the second set of interconnects 404B is then scaled using a shrink process. In one embodiment, no shrink or a less aggressive shrink is used during the formation of the first set of interconnects 404A, and a more aggressive shrink is used during the formation of the second set of interconnects 404B, thereby producing a first set of interconnects 404A with a larger size than the second set of interconnects 404B.

A method for forming interconnects having different sizes according to one embodiment makes use of a lithography double patterning process to pattern a first set of interconnect openings in photo resist during a first exposure, and subsequently reducing the sizes of the first set of openings by a shrink process. The image of the openings in the photo resist is transferred into a hard mask. A second set of interconnect openings is patterned in a second photo resist layer during a second exposure, and the sizes of the second set of openings is reduced by a shrink process. The image of the openings in the second photo resist layer is transferred into the hard mask. In one embodiment, the openings in the hard mask after the two lithography steps have a sub-resolution pitch. In one embodiment, the openings may be holes. In another embodiment, the openings may be trenches.

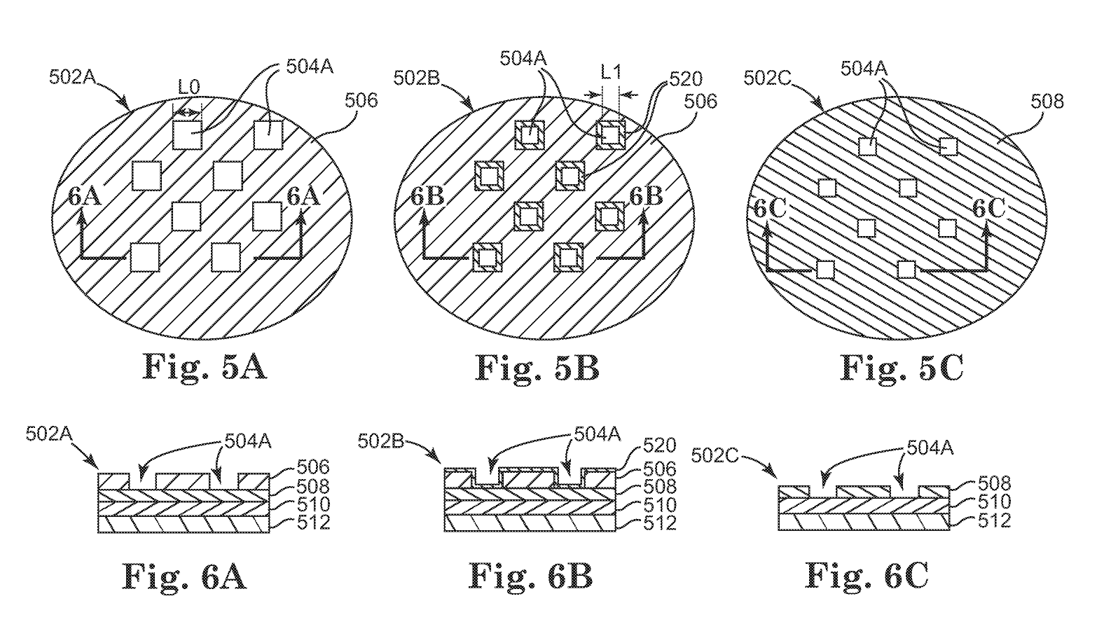

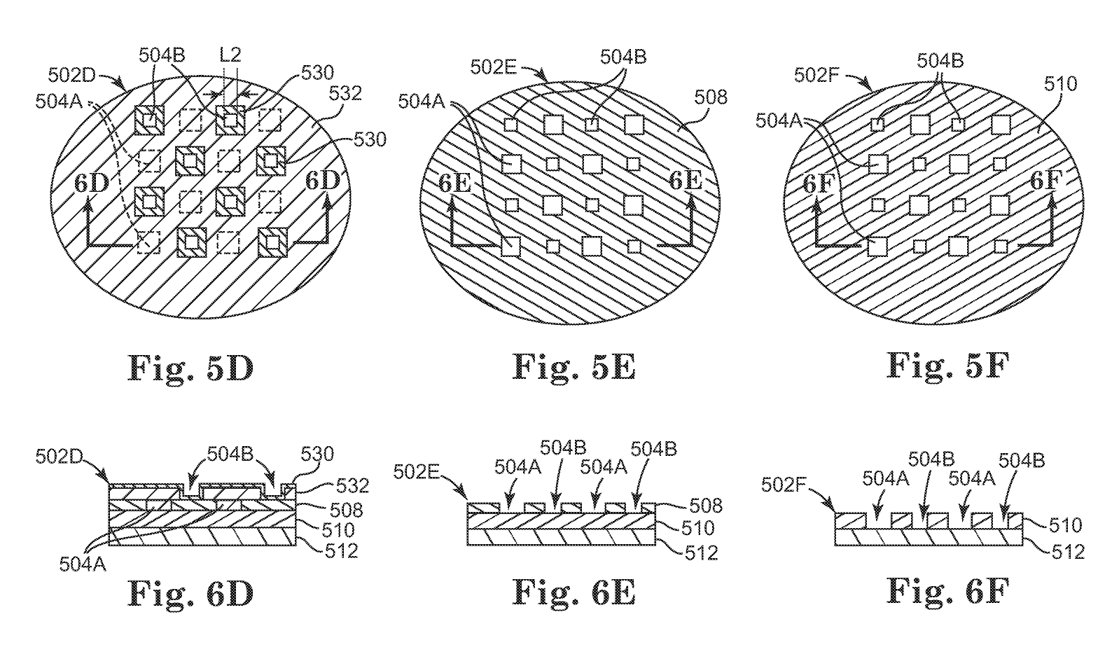

FIGS. 5A-5F are diagrams illustrating a top view of a structure with a semiconductor substrate and illustrating a method for forming interconnects of different sizes using a combination of a double exposure lithography process and a plasma-assisted shrink process according to one embodiment. FIGS. 6A-6F are diagrams illustrating cross-sectional views taking along sections 6A-6A to 6F-6F, respectively, of the structures shown in FIGS. 5A-5F, respectively, according to one embodiment. Referring to FIGS. 5A and 6A, structure 502A includes a semiconductor substrate layer 512, an inter-level dielectric (ILD) layer 510, a hard mask (HM) layer 508, and a patterned photo resist layer 506.

In one embodiment, semiconductor substrate layer 512 is a silicon wafer with circuitry, such as transistors (e.g., with source and drain areas and gates), and insulation areas (e.g., shallow trench isolation (STI) and/or silicon-on-insulator buried-oxide (SOI BOX insulation). In one embodiment ILD 510 includes a dielectric liner (e.g. Si3N4 in the form of a single or dual stress liner) that covers the semiconductor substrate layer 512, and a dielectric (e.g., borophosphorous silicate glass (BPSG), phospho-silicate glass (PSG), undoped oxide, a low-k dielectric, or any combination thereof) where the interconnects will be embedded. In one embodiment, HM 508 is a single or multiple hard mask (e.g., Si3N4, SiC, or SiCN as a single dielectric hard mask; an oxide/nitride (e.g., SiO2/Si3N4, SiC/SiCN) dual hard mask; an amorphous carbon hard mask, or a metal hard mask (e.g., TiN or TaN)) that is deposited on top of the ILD 510.

In one embodiment, photo resist layer 506 is deposited on the HM 508. In another embodiment, a bottom anti-reflective coating (BARC) is first deposited on the HM 508, and then the photo resist layer 506 is deposited on the BARC layer. The photo resist layer 506 is exposed using a first photo mask, and developed, to form the pattern of interconnect openings 504A shown in FIGS. 5A and 6A. As shown in FIG. 5A, the size of the openings 504A in the resist layer 506 prior to the shrink process is represented by L0.

Referring to FIGS. 5B and 6B, a polymer layer 520 is formed on the resist layer 506, thereby forming structure 502B. As shown in FIG. 6B, the polymer layer 520 covers the horizontal surfaces and vertical surfaces (i.e., the vertical sidewalls of the openings 504A) of the resist layer 506, and covers the horizontal surfaces of the HM 508 in the regions of the openings 504A. In one embodiment, the polymer layer 520 is a thin polymer film (e.g., about 1 nm-20 nm) that is deposited by a plasma based on a carbon and fluorine chemistry (e.g., CHF3, CF4, C2F6, C4F8 with optional additions of Ar, He, CO, O2, N2, H2).

After the plasma-assisted deposition of the polymer layer 520, a short anisotropic etch (e.g., chemistry based on O2/CF4, O2, H2/N2, He/N2 or other combinations) is performed to remove the polymer from the horizontal surfaces of the resist layer 506 and the horizontal surfaces of the HM 508 (or BARC, if present) in the regions of the openings 504A, so that only the polymer film 520 at the vertical surfaces of the resist layer 506 remains. This sequence of polymer deposition and polymer etching can be repeated until a desired reduction of the openings 504A for a first set of interconnects is achieved. As shown in FIG. 5B, the size of the openings 504A in the resist layer 506 after the plasma-assisted shrink process is represented by L1, which is smaller than L0.

Referring to FIGS. 5C and 6C, after the plasma-assisted shrink process (described above with respect to FIGS. 5B and 6B), an anisotropic etching process is performed to etch the pattern of the reduced size openings 504A (shown in FIG. 5B) into the HM 508 (and the BARC, if present) using the resist layer 506 as an etch mask. The resist layer 506 is then stripped (as is the BARC, if present), thereby forming the structure 502C shown in FIGS. 5C and 6C.

Referring to FIGS. 5D and 6D, in the illustrated embodiment, a photo resist layer 532 is deposited on the HM 508, including the interconnect opening regions 504A within the HM 508. In another embodiment, a bottom anti-reflective coating (BARC) is first deposited on the HM 508, and then the photo resist layer 532 is deposited on the BARC layer. The photo resist layer 532 is exposed using a second photo mask, and developed, to form the pattern of interconnect openings 504B shown in FIGS. 5D and 6D.

A polymer layer 530 is formed on the resist layer 532, thereby forming structure 502D. As shown in FIG. 6D, the polymer layer 530 covers the horizontal surfaces and vertical surfaces (i.e., the vertical sidewalls of the openings 504B) of the resist layer 532, and covers the horizontal surfaces of the HM 508 in the regions of the openings 504B. In one embodiment, the polymer layer 530 is a thin polymer film (e.g., about 1 nm-20 nm) that is deposited by a plasma based on a carbon and fluorine chemistry (e.g., CHF3, CF4, C2F6, C4F8 with optional additions of Ar, He, CO, O2, N2, H2).

After the plasma-assisted deposition of the polymer layer 530, a short anisotropic etch (e.g., chemistry based on O2/CF4, O2, H2/N2, He/N2 or other combinations) is performed to remove the polymer from the horizontal surfaces of the resist layer 532 and the horizontal surfaces of the HM 508 (or BARC, if present) in the regions of the openings 504B, so that only the polymer film 530 at the vertical surfaces of the resist layer 532 remains. This sequence of polymer deposition and polymer etching can be repeated until a desired reduction of the openings 504B for a second set of interconnects is achieved. As shown in FIG. 5D, the size of the openings 504B in the resist layer 532 after the plasma-assisted shrink process is represented by L2, which is smaller than L1 (i.e., a more aggressive plasma-assisted shrink process was used for the second set of openings 504B than the first set of openings 504A).

Referring to FIGS. 5E and 6E, after the plasma-assisted shrink process for the second set of openings 504B (described above with respect to FIGS. 5D and 6D), an anisotropic etching process is performed to etch the pattern of the reduced size openings 504B (shown in FIG. 5D) into the HM 508 (and the BARC, if present) using the resist layer 532 as an etch mask. The resist layer 532 is then stripped (as is the BARC, if present), thereby forming the structure 502E shown in FIGS. 5E and 6E.

Referring to FIGS. 5F and 6F, an anisotropic etching process is performed to etch the pattern of the interconnect openings 504A and 504B from the HM 508 into the ILD 510 (including the dielectric liner or stress liner) using the HM 508 as an etch mask. The HM 508 is later removed in one embodiment, as shown by structure 502F. The openings 504A and 504B in the ILD 510 are filled with a conductive material to form interconnects of two different sizes. In the case of a metal HM 508, the metal hard mask film can be removed during a chemical-mechanical polishing (CMP) step or etch back step after interconnect fill (e.g., W-plug fill or Al-fill or Cu-fill with respective Ti/TiN or TaN/Ta liners). In the case of a dielectric HM 508, the hard mask may remain, or can optionally also be removed after the CMP step after interconnect fill.

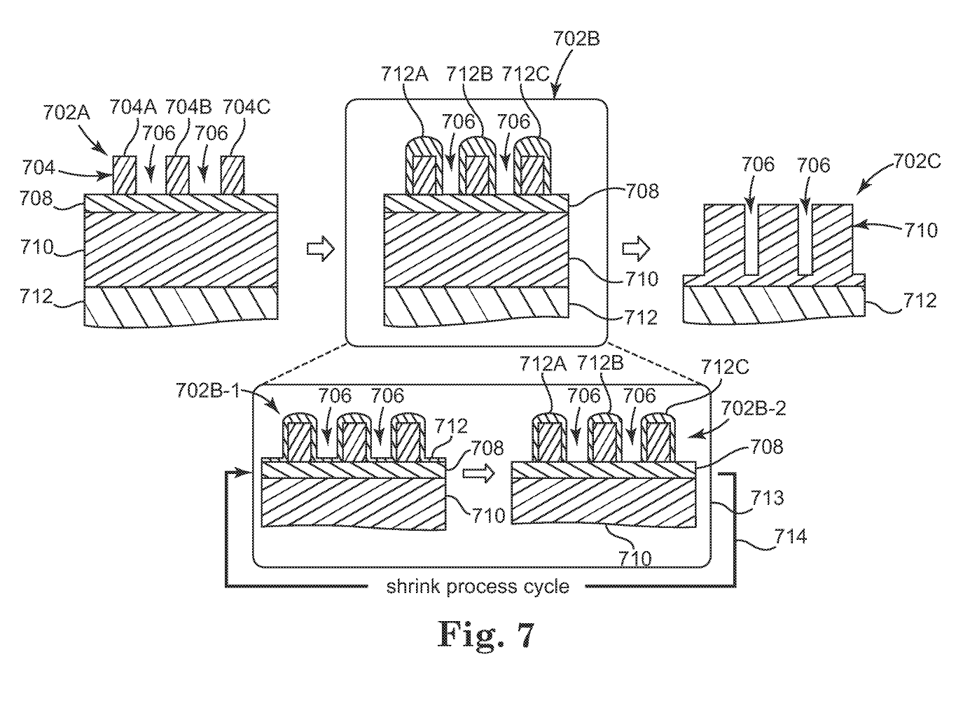

In the embodiment described above with respect to FIGS. 5A-5F and 6A-6F, interconnects of two different sizes are generated. In another embodiment, the process is extended to provide interconnects of three or more different sizes. In the embodiment described above with respect to FIGS. 5A-5F and 6A-6F, a moderate shrink is performed for the first set of interconnect openings 504A, followed by a more aggressive shrink for the second set of interconnect openings 504B. In another embodiment, this sequence is reversed (i.e., an aggressive shrink is performed first followed by a moderate shrink). In yet another embodiment, the shrink process is used in only one of the lithography steps of the double exposure. The shrink process according to one embodiment is described in further detail below with reference to FIG. 7.

FIG. 7 is a diagram illustrating a plasma-assisted shrink process according to one embodiment. The process begins with a structure 702A, which includes a semiconductor substrate layer (e.g., semiconductor wafer) 712, a dielectric layer 710 formed on the semiconductor substrate layer 712, a bottom anti-reflective coating (BARC) layer 708 formed on the dielectric layer 710, and a patterned photo resist layer 704 on the BARC 708. The photo resist layer 704 has been patterned to produce photo resist islands 704A-704C, and a pattern of interconnect openings 706. A plasma-assisted shrink process is then performed on structure 702A to produce a structure 702B with interconnect openings 706 that are reduced in size.

The plasma-assisted shrink process is shown in additional detail in block 713. A polymer layer 712 is formed on the patterned resist layer 704 of structure 702A using a plasma-assisted deposition, thereby forming structure 702B-1. As shown in FIG. 7, the polymer layer 712 covers the horizontal and vertical surfaces of the patterned resist layer 704, and covers the horizontal surfaces of the BARC 708 in the regions of the openings 706. After the plasma-assisted deposition of the polymer layer 712, a short anisotropic etch is performed to remove the polymer from the horizontal surfaces of the BARC 708 in the regions of the openings 706, so that only the polymer film portions 712A-712C remain at the sidewalls of the resist 704A-704C, thereby forming structure 702B-2. This sequence of polymer deposition and polymer etching can be repeated as indicated by arrow 714 until a specified size of the openings 706 has been achieved.

After the plasma-assisted shrink is complete, an anisotropic etching process is performed to etch the pattern of the reduced size openings 706 into the BARC 708 and the dielectric 710. The resist layer 704 and the BARC 708 are removed, thereby forming the structure 702C with reduced size interconnect openings 706 formed in the dielectric 710. The interconnect openings 706 are then filled with conductive material to form interconnects therein.

For device and circuit designers, it would be very beneficial if two or more different interconnect sizes were available. One embodiment provides a method for producing interconnects of different sizes in a circuit layout. This allows designers to create various sets of circuits that will address different application types from “low power” towards “high performance” or “ultra low cost”. It is expected that with further scaling, the contact resistance will be a dominant part of the total resistance of the transistor, which is highly dependent on the geometrical size. That means that the capability of driving currents, which is a characteristic of an active device like a MOSFET, could be degraded in future technologies that use smaller geometrical sizes. One embodiment avoids this problem by allowing the use of smaller contacts where area consumption is important and larger contacts where driver performance is important.

The method of interconnect patterning making use of the interconnect opening shrink technique described above can be applied to one or more contact or via patterning levels during the chip manufacturing sequence. In one embodiment, it may be applied to the patterning of contacts to the source/drain regions and the gates of transistors of a typical CMOS device. In this application, the contacts may land on non-silicided as well as to silicided gate and source/drain regions. Alternatively, the contacts may land on high k/metal gate stacks or any version of multigate stacks, like for example, dual gate or Fin-FET structures. In other embodiments, it may be used to contact devices with single or dual stress liners or devices making use of SiGe-stress or devices in SOI-technologies. In another embodiment, it may be applied for the via patterning between subsequent metal levels within the interconnect stack of a multi-level metallization. In this application, the vias function as electrical contacts between the different metal levels. In other embodiments, it may be applied for contact patterning to Bipolar, BiCMOS, analog, mixed signal, power semiconductor, MEMS or RF devices. In other embodiments, it may be applied for via patterning in the interconnect stacks of Bipolar, BiCMOS, analog, mixed signal, power semiconductor, MEMS or RF chips.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming interconnects, comprising:
etching a first set of openings in a hard mask using a first photo resist layer with a first pattern of openings as a first etch mask;
etching a second set of openings in the hard mask using a second photo resist layer with a second pattern of openings as a second etch mask; and
shrinking the openings in at least one of the first pattern and the second pattern prior to etching the openings in the hard mask.

2. The method of claim 1, and further comprising:
etching a third set of openings in a dielectric layer using the hard mask as an etch mask.

3. The method of claim 2, and further comprising:
filling the third set of openings with a conductive material, thereby forming first and second sets of interconnects.

4. The method of claim 3, wherein the interconnects in the first set each have a first size and the interconnects in the second set each have a second size, and wherein the first size is different than the second size.

5. The method of claim 3, wherein the interconnects are contacts.

6. The method of claim 3, wherein the interconnects are conductive vias.

7. The method of claim 1, wherein the openings in only one of the first pattern or the second pattern are shrunk prior to etching the openings in the hard mask.

8. The method of claim 1, wherein the openings in both of the first pattern and the second pattern are shrunk prior to etching the openings in the hard mask.

9. The method of claim 8, wherein a different amount of shrinking is performed for the first pattern than the second pattern.

10. The method of claim 1, wherein shrinking the openings comprises:
depositing a polymer layer on at least one of the first photo resist layer and the second photo resist layer, thereby covering horizontal surfaces and vertical surfaces of the at least one photo resist layer with polymer material; and
etching the polymer layer to remove polymer material from the horizontal surfaces while leaving polymer material on the vertical surfaces of the at least one photo resist layer.

11. The method of claim 10, and further comprising:
repeating the depositing a polymer layer and etching the polymer layer steps until a specified opening size has been achieved.

12. The method of claim 10, wherein the polymer layer is deposited using a plasma-assisted deposition.

13. A method of forming interconnects, comprising:
forming a first pattern of openings in a first photo resist layer using a first photo mask;
etching a first set of openings in a hard mask using the patterned first photo resist layer as an etch mask;
forming a second pattern of openings in a second photo resist layer using a second photo mask;
etching a second set of openings in the hard mask using the patterned second photo resist layer as an etch mask; and
shrinking the openings in at least one of the first pattern and the second pattern prior to etching the openings in the hard mask, wherein the shrinking causes the openings in the hard mask to have multiple sizes.

14. The method of claim 13, and further comprising:
etching a third set of openings in a dielectric layer using the hard mask as an etch mask.

15. The method of claim 14, and further comprising:
filling the third set of openings with a conductive material, thereby forming first and second sets of interconnects, wherein the interconnects in the first set each have a first size and the interconnects in the second set each have a second size, and wherein the first size is different than the second size.

16. The method of claim 13, wherein the openings in only one of the first pattern or the second pattern are shrunk prior to etching the openings in the hard mask.

17. The method of claim 13, wherein the openings in both of the first pattern and the second pattern are shrunk prior to etching the openings in the hard mask.

18. The method of claim 17, wherein a different amount of shrinking is performed for the first pattern than the second pattern.

19. The method of claim 13, wherein shrinking the openings comprises:
depositing a polymer layer on at least one of the patterned first photo resist layer and the patterned second photo resist layer, thereby covering horizontal surfaces and vertical surfaces of the at least one photo resist layer with polymer material; and
etching the polymer layer to remove polymer material from the horizontal surfaces while leaving polymer material on the vertical surfaces of the at least one photo resist layer.

20. The method of claim 19, and further comprising:
repeating the depositing a polymer layer and etching the polymer layer steps until a specified opening size has been generated.

21. The method of claim 19, wherein the polymer layer is deposited using a plasma-assisted deposition.

22. A method of forming interconnects, comprising:
forming a first pattern of openings in a first photo resist layer using a first photo mask;
forming a second pattern of openings in a second photo resist layer using a second photo mask;
performing a plasma-assisted shrinking of the openings in at least one of the first photo resist layer and the second photo resist layer;
forming a set of openings in a layer based on the first pattern and the second pattern; and
filling the set of openings with a conductive material, thereby forming interconnects with multiple sizes.

23. A method of forming a third set of openings, comprising:
etching a first set of openings in a hard mask using a first photo resist layer with a first pattern of openings as a first etch mask;
etching a second set of openings in the hard mask using a second photo resist layer with a second pattern of openings as a second etch mask;
shrinking the openings in at least one of the first pattern and the second pattern prior to etching the openings in the hard mask; and
etching a third set of openings in a dielectric layer using the hard mask as an etch mask.

24. The method of claim 23, wherein the first, second and third set of openings are holes.

25. The method of claim 23, wherein the first, second and third set of openings are trenches.
